(19) United States
(12) Patent Application Publication
(10) Pub. No.: US 2012/0070966 A1
(43) Pub. Date: Mar. 22, 2012

(54) METHOD FOR MANUFACTURING SEMICONDUCTOR ELEMENT

(75) Inventors: Hiroshi Katsumata, Kanagawa-ken (JP); Junji Kataoka, Kanagawa-ken (JP); Toshiyuki Terada, Kanagawa-ken (JP); Yoshiharu Kouji, Kanagawa-ken (JP); Hidenori Hanyu, Kanagawa-ken (JP); Norikazu Sugawara, Kanagawa-ken (JP); Shinji Onduka, Kanagawa-ken (JP)

(73) Assignee: Kabushiki Kaisha Toshiba, Tokyo (JP)

(21) Appl. No.: 13/226,727

(22) Filed: Sep. 7, 2011

(30) Foreign Application Priority Data
Sep. 16, 2010 (JP) 2010-208547

(51) Int. Cl. H01L 21/20

(52) U.S. Cl. 438/479; 257/E21.09

(57) ABSTRACT

A method for manufacturing a semiconductor element includes etching a surface of a substrate by a dry etching processing, performing a first heat treatment for the surface of the substrate in an atmosphere including halogen, and forming a nitride semiconductor on the surface of the substrate.

### CROSS-REFERENCE TO RELATED APPLICATION

This application is based upon and claims the benefit of priority from Japanese Patent Application No. 2010-208547, filed on Sep. 16, 2010, the entire contents of which are incorporated herein by reference.

### FIELD

Embodiments described herein relate generally to a method for manufacturing semiconductor element.

### BACKGROUND

A semiconductor element using nitride semiconductor is developed. The nitride semiconductor may be formed on a sapphire or SiC (Silicon Carbide) substrate by using MOCVD (Meal Organic Chemical Vapor Deposition). Performance of the semiconductor element using the nitride semiconductor depends on quality of a crystal of the nitride semiconductor formed on the sapphire substrate.

JP-A2010-10363 (KOKAI) discloses a technique to form the nitride semiconductor on a sapphire substrate for producing light-emitting diode (LED). In this reference, surface of the sapphire substrate has a concavo-convex pattern, for example, circular cone and circular cylinder. The technique improves efficiency of acquiring emission light from the crystal of the nitride semiconductor and the sapphire substrate. As a result, the technique realizes stronger emission intensity of LED.

The sapphire substrate is made of stable crystals. Dry etching processing is popular to etch a surface of the sapphire substrate. However, the dry etching processing may give damage on the surface of the sapphire substrate. When crystal of the nitride semiconductor is formed on the damaged sapphire substrate, the crystal of the nitride semiconductor easily degrades. As a result, it is difficult to produce high intensity LED.

Therefore, a technique is required to form the crystal of the nitride semiconductor with a higher quality on the surface of the sapphire substrate, even if the dry etching processing is used.

### DESCRIPTION OF THE DRAWINGS

Aspects of this disclosure will become apparent upon reading the following detailed description and upon reference to the accompanying drawings. The description and the associated drawings are provided to illustrate embodiments of the invention and not limited to the scope of the invention.

FIG. 1 is a cross-sectional diagram of a semiconductor element according to an embodiment;

FIG. 2A is a cross-sectional diagram explaining a manufacturing process of semiconductor element;

FIG. 2B is a cross-sectional diagram explaining a manufacturing process of semiconductor element;

FIG. 3A is a cross-sectional diagram explaining a manufacturing process of semiconductor element;

FIG. 3B is a cross-sectional diagram explaining a manufacturing process of semiconductor element;

FIG. 4 is a cross-sectional diagram of a MOCVD device;

FIG. 5 is a flowchart for explaining a growth process of the nitride semiconductor;

FIG. 6A is a photograph by a SEM showing convex portions formed on a surface of the PSS;

FIG. 6B is a photograph by a SEM showing convex portions formed on a surface of the PSS;

FIG. 7A is a photograph by a differential microscope showing a n-GaN buffer layer with chlorine pre-treatment formed on a surface of the PSS;

FIG. 7B is a photograph by the differential microscope showing an n-GaN layer without chlorine pre-treatment formed on a surface of the PSS;

FIG. 8A is a photograph by a SEM showing a cross-section of the PSS having the n-GaN buffer layer formed with chlorine pre-treatment;

FIG. 8B is a photograph by a SEM showing a cross-section of the PSS having the n-GaN layer formed without chlorine pre-treatment;

FIG. 9A is a photograph by a SEM showing a cross-section of the convex portion formed on PSS having the n-GaN buffer layer formed with chlorine pre-treatment;

FIG. 9B is a photograph by a SEM showing a cross-section of the convex portion formed on the PSS having the n-GaN layer formed without chlorine pre-treatment;

FIG. 10 is a graph showing a PL spectrum of the n-GaN buffer layer;

FIG. 11 is a graph showing a PL spectrum of the n-GaN layer;

FIG. 12 is a graph showing a micro-raman scattering spectrum of the PSS;

FIG. 13 is a table showing evaluation results;

FIG. 14 is a table showing half width of XRC; and

FIG. 15 is a table showing measurement data of a micro-raman scattering spectrum.

### DETAILED DESCRIPTION

According to one aspect of the invention, a method for manufacturing a semiconductor element includes etching a surface of a substrate by a dry etching processing, performing a first heat treatment for the surface of the substrate in an atmosphere including halogen, and forming a nitride semiconductor on the surface of the substrate.

The embodiments will be explained with reference to the accompanying drawings. Note that, the same reference numerals are given to the same configuration among embodiments, and the description will be omitted.

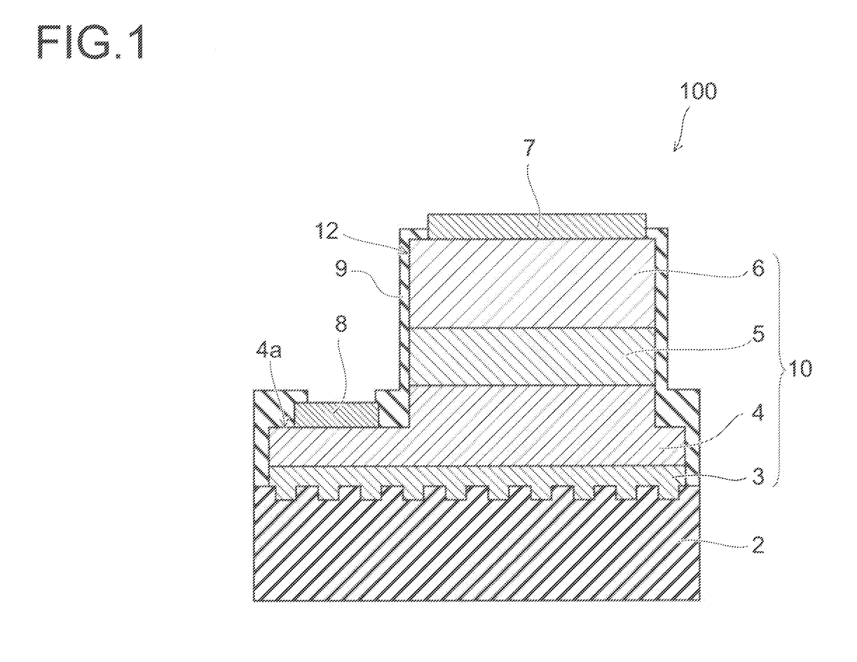

FIG. 1 is a cross-sectional diagram of a semiconductor element 100. The semiconductor element 100 is an LED including a nitride semiconductor of GaN (Gallium Nitride). The semiconductor element 100 includes a sapphire substrate 2. The surface of the sapphire substrate 2 has a concavo-convex pattern.

A multi layer 10 is formed on the sapphire substrate 2. In the multi layer 10, a n-GaN buffer layer 3, a n-GaN contact layer 4, an emission layer 5 and a p-GaN layer 6 are piled. The emission layer 5 may include multiquantum well structure in which an InGaN quantum well layer and a GaN barrier layer are piled alternately.

As shown in FIG. 1, the multi layer 10 has a mesa structure in which the emission layer 5 and the p-GaN layer 6 are etched. A surface 4a of the n-GaN contact layer 4 is exposed by etching the emission layer 5 and the p-GaN layer 6. A p-electrode 7 is placed at the p-GaN layer 6. A n-electrode 8 is placed at the surface 4a of the n-GaN contact layer 4. A passivation film 9 is formed at sides of the mesa structure and a part of the surface 4a of the n-GaN contact layer 4.

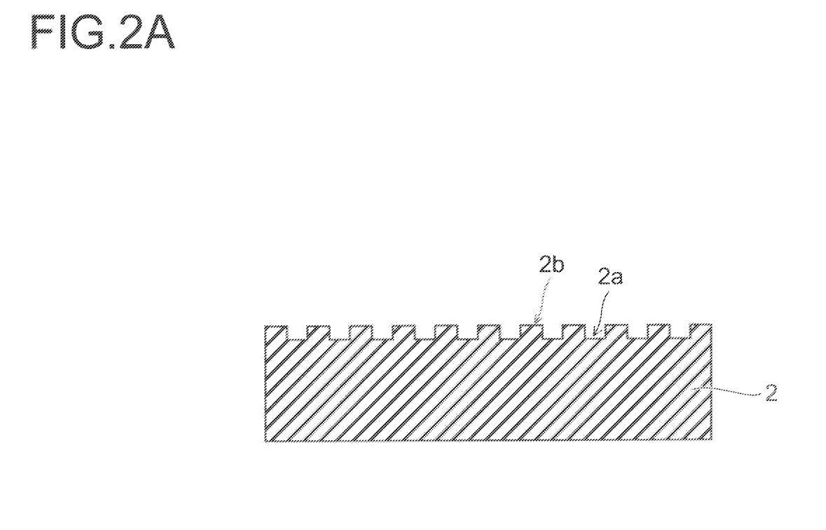

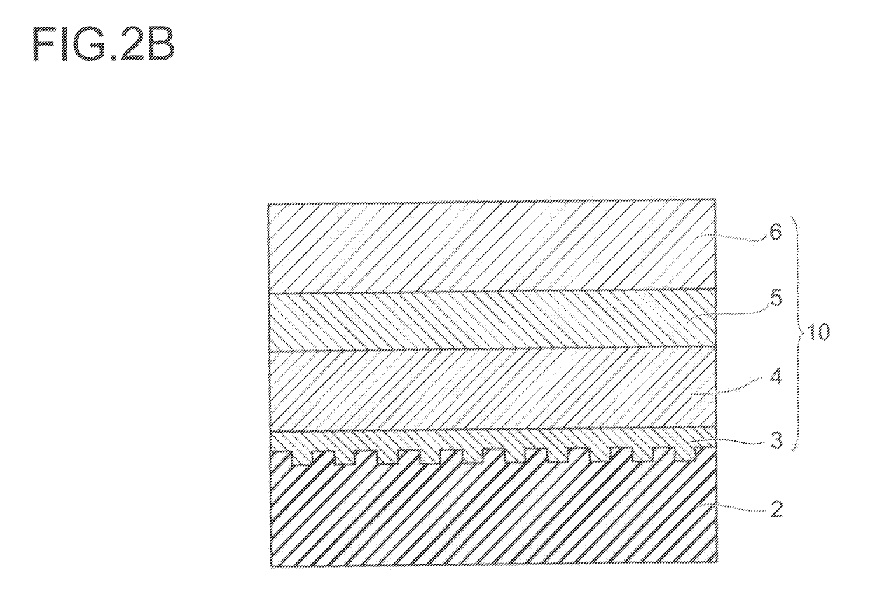

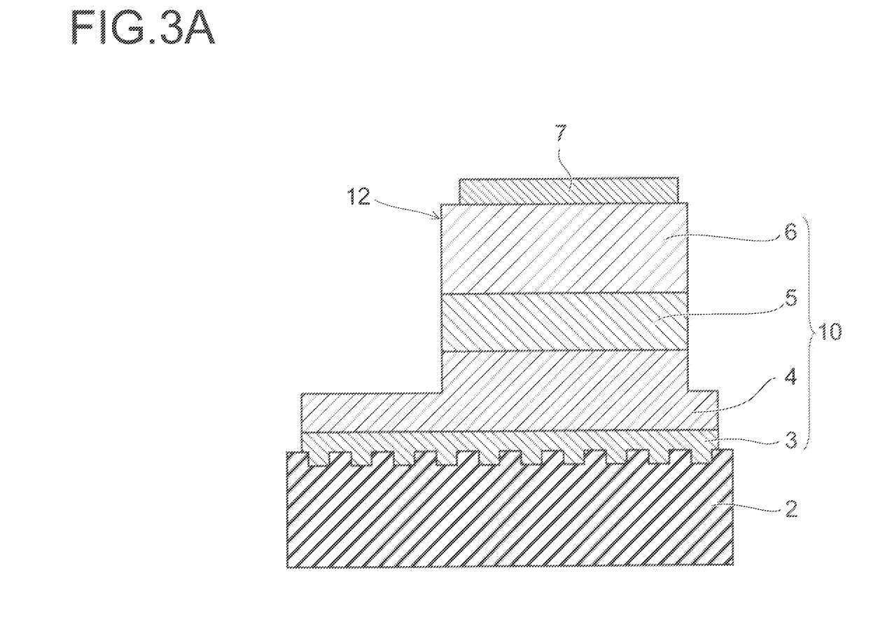

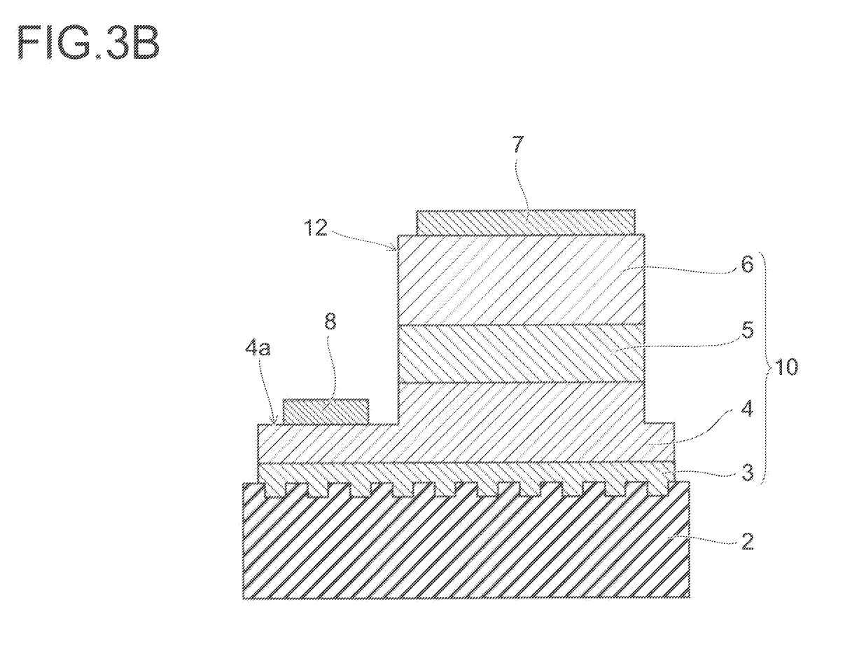

Next, we explain a method for manufacturing semiconductor element 100 with reference to FIG. 2 and FIG. 3. In the method for manufacturing semiconductor element 100 according to the embodiment, after the sapphire substrate 2 is etched by the dry etching processing, a heat treatment is performed for the surface of the sapphire substrate 2 in a halogen atmosphere. Then, the nitride semiconductor is formed at the surface of the sapphire substrate 2.

FIG. 2A is a cross-sectional diagram of the sapphire substrate 2. The surface of the sapphire substrate 2 has concave portions 2a and convex portions 2b. The sapphire substrate 2 may be a wafer. The concave portions 2a are formed by using resist as a mask. For example, the concave portions 2a may be formed by the dry etching process using a chlorine gas as an etching gas with an RIE (Reactive Ion Etching) device of ICP (Inductively Coupled Plasma).

In the RIE device, the surface of the sapphire substrate 2 is sputtered by plasma-excited ions which are accelerated by electric field. Moreover, etching is accelerated by chemical reaction using chlorine. Due to them, the RIE device can form the concave portions 2a on the surface of the sapphire substrate 2, despite the sapphire substrate 2 being chemically stable.

After the dry etching process using the RIE device is completed, mixed solution of sulfuric acid and hydrogen peroxide water with a ratio of one to one, is provided to the surface of the sapphire substrate 2 for five minutes. Accordingly, etching residue is removed from the surface of the sapphire substrate 2.

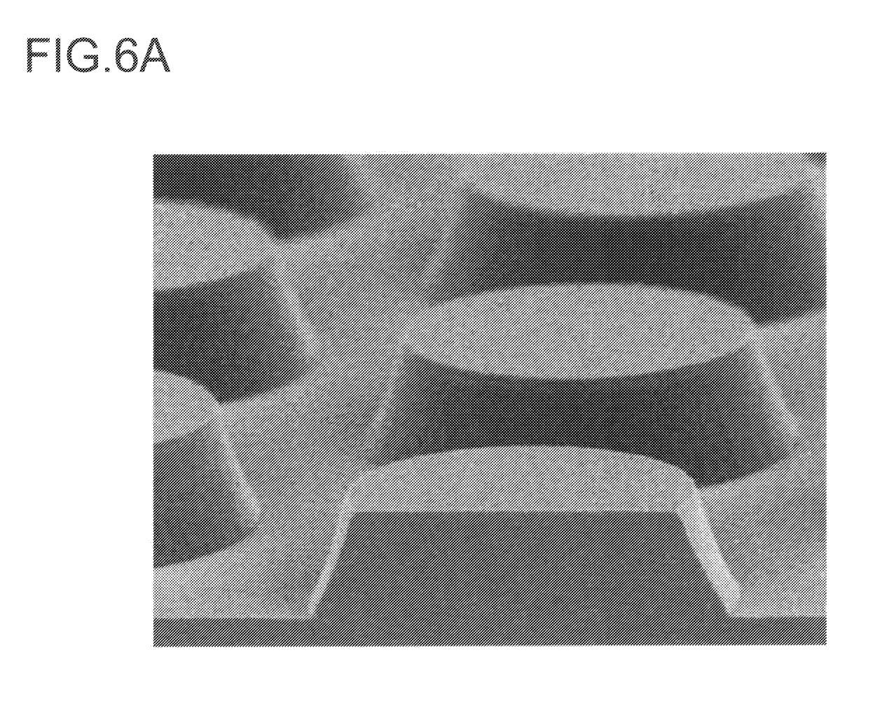

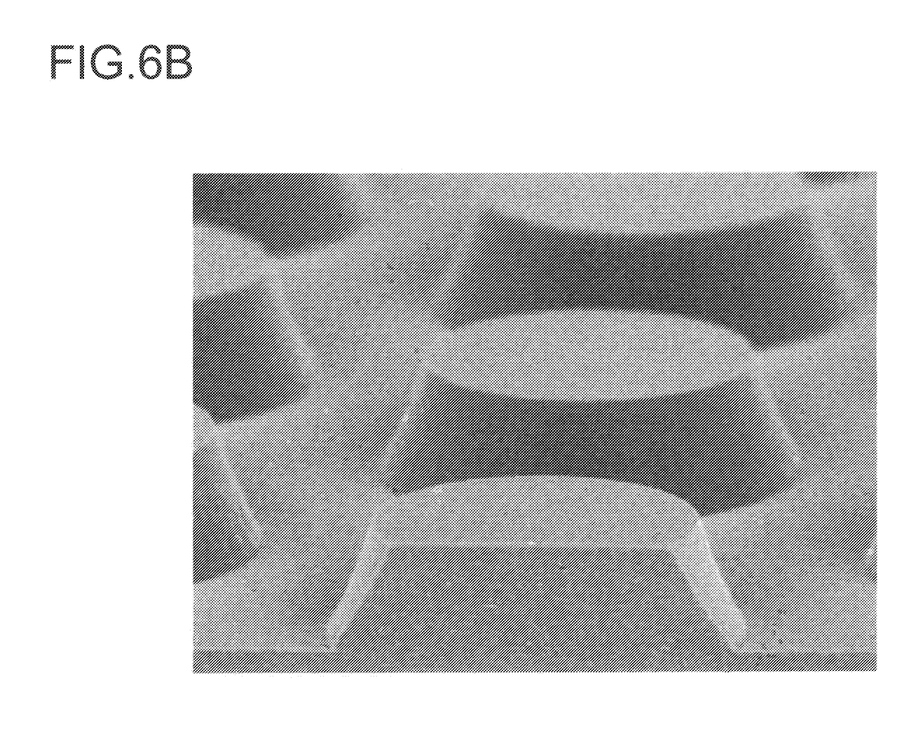

For example, the concave portions 2a is formed by forming a circular resist mask on the surface of the sapphire substrate 2 and performing the dry etching process. As a result, each of the convex portions 2b is formed as a circular truncated cone having diameter of 3 μm in a base plane, taper angle of 65° in a side wall and height of 1 μm, as shown in FIG. 6. Pitch distance between two of the convex portions 2b is at least about 5 μm. Each of the convex portions 2b may be placed at a corner of a hexagonal shape. The surface of the sapphire substrate 2 may be roughened by the dry etching process. Hereinafter, the sapphire substrate 2 having the convex portions 2b is referred to as a PSS (Patterned Sapphire Substrate) 2.

Next, the multi layer 10 including the n-GaN buffer layer 3, the n-GaN contact layer 4, the emission layer 5 and the p-GaN layer 6 on the PSS 2, as shown in FIG. 2B.

Next, the p-electrode 7 is formed at surface of the p-GaN layer 6, as shown in FIG. 3A. Then, the p-GaN layer 6, the emission layer 5, and part of the n-GaN contact layer 4 are etched to form the mesa structure.

Next, the n-electrode 8 is formed at the surface 4a of the n-GaN contact layer 4 which is exposed at bottom of the mesa structure, as shown in FIG. 3B. Then, the passivation film 9 is formed at sides 12 of the mesa structure and a part of the surface 4a of the n-GaN contact layer 4 to complete the semiconductor element 100 of FIG. 1.

In the semiconductor element 100, emission light is emitted from the emission layer 5 by flowing electric current from the p-electrode 7 to the n-electrode 8. The emission light is propagated inside the multi layer 10. Part of the emission light is released to outside of the multi layer 10. In general, most of the emission light repeats reflecting inside the multi layer 10 due to a difference of refractive indexes between the nitride semiconductor and the sapphire substrate 2. As a result, most of the emission light is absorbed into the emission layer 5 and the p-electrode 7, and then most of the emission light attenuates.

On the other hand, in this embodiment, the semiconductor element 100 has a concavo-convex pattern at interfacial surface of between the sapphire substrate 2 and the n-GaN buffer layer 3 in order to inhibit the reflection inside the multi layer 10. Accordingly, the emission light is propagated inside the sapphire substrate 2. As a result, less emission light attenuates inside the semiconductor element 100 and more emission light is emitted from the multi layer 10 and the sapphire substrate 2 to outside. Therefore, the semiconductor element 100 realizes stronger emission intensity.

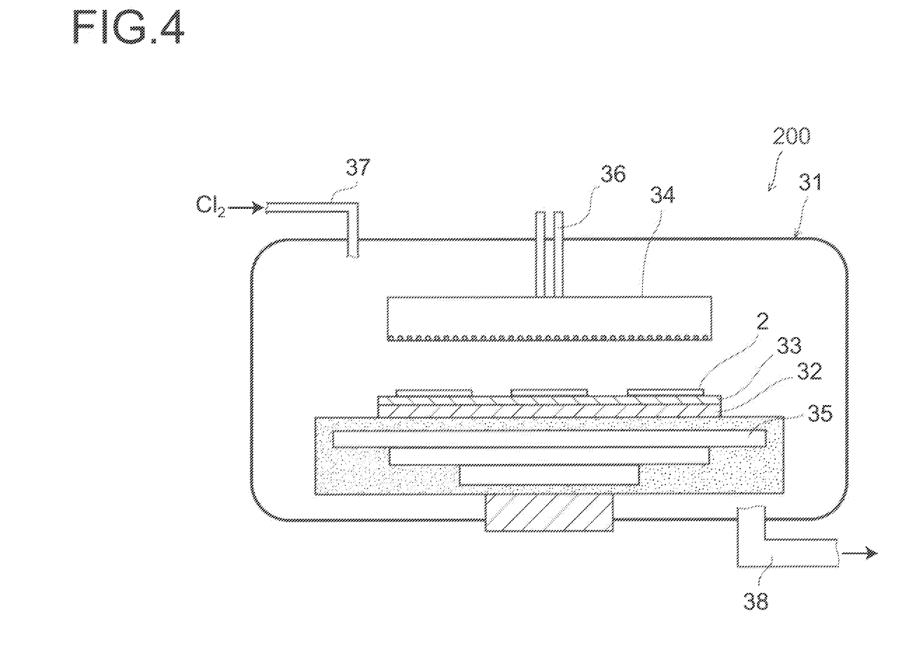

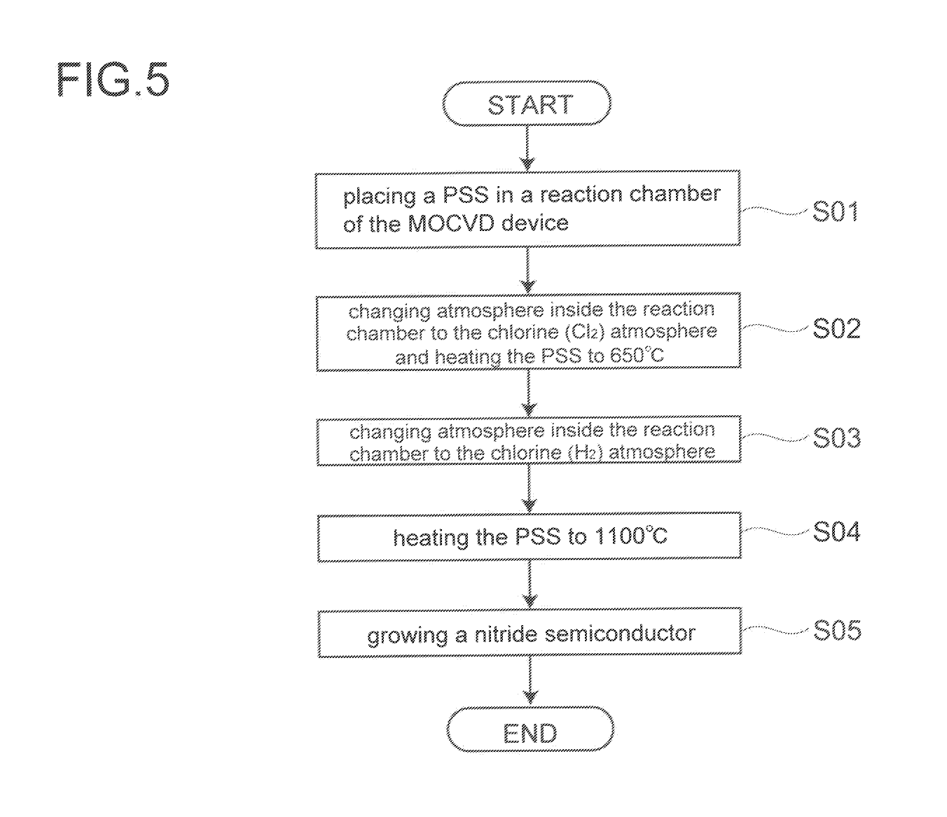

Next, we explain a method for forming the nitride semiconductor included in the multi layer 10 with reference to FIG. 4 and FIG. 5. FIG. 4 is a cross-sectional diagram of a MOCVD device 200 which makes the nitride semiconductor grows larger. FIG. 5 is a flowchart for explaining a growth process of the nitride semiconductor.

As shown in FIG. 4, the MOCVD device 200 includes a reaction chamber 31, a susceptor 32, a wafer tray 33, a shower head 34, a lamp heater 35, a duct 36, a gas port 37, and an exhaust port 38. The susceptor 32, the wafer tray 33, the shower head 34, the lamp heater 35, and the duct 36 exist in the reaction chamber 31. The nitride semiconductor grows larger in the reaction chamber. The wafer tray 33 is placed on the susceptor 32. The lamp heater 35 heats the susceptor 32. The duct 36 supplies a raw gas. The shower head 34 uniformly sprays the raw gas on whole surface of the wafer tray 33. The gas port 37 supplies a gas including chlorine (Cl₂) into the reaction chamber 31. The exhaust port 38 exhausts the gas from inside of the reaction chamber 31 by a vacuum pump (not shown).

In the growth process of the nitride semiconductor shown in FIG. 5, PSSs 2 are set inside the reaction chamber 31 in a step S01. Specifically, the PSSs 2 are placed on the wafer tray 33 at an outside the reaction chamber 31. The wafer tray 33 is brought to the inside of the reaction chamber 31 through a vacuum gate (not shown), and placed on the susceptor 32.

Next, the lamp heater 35 heats the susceptor 32 with reducing the pressure by the vacuum pump (not shown) inside of the reaction chamber. Then, the gas including chlorine (Cl₂) is supplied into the reaction chamber 31 in a step S02.

For example, a chlorine (Cl₂) gas and a nitrogen (N) gas may be supplied with a ratio of 4 to 1. The PSSs 2 are heated to about 650° C. through the wafer tray 33. Then, a heat treatment is performed for about 20 minutes in a chlorine (Cl₂) atmosphere. Hereinafter, the heat treatment is referred to as a chlorine pretreatment.

Then, the chlorine (Cl₂) gas stops being supplied and the chlorine (Cl₂) gas is attenuated by the nitrogen (N) gas. Accordingly, the chlorine (Cl₂) atmosphere is changed to a nitrogen (N) atmosphere. This promotes sublimation of chloride exits on the surface of the PSS 2.

Next, the nitrogen (N) atmosphere of inside the reaction chamber 31 is changed to a hydrogen (H) atmosphere in a step S03. For example, the nitrogen (N) gas is exhausted by reducing the pressure of inside the reaction chamber 31, and then a hydrogen (H) gas is supplied into the reaction chamber 31.

In a step S04, the susceptor 32 is heated by the lamp heater 35. Because of this, temperature of the PSS 2 increases to 1100° C. Then, a heat treatment is performed for about 10 minutes. The PSS2 may be maintained at a temperature of 1000° C. to 1500° C.

Reaction product including chloride is removed from the surface of the PSS 2 by increasing the temperature of the PSS 2 to at least 1000° C. and performing the heat treatment in the hydrogen (H) atmosphere. In above process, halogen gas may be used instead of chlorine gas. Also, inert gas such as argon (Ar) gas may be used instead of nitrogen gas.

In a step S05, the nitride semiconductor is formed on the PSS 2. First, the temperature of the PSS 2 decreases to 785° C. Subsequently, the hydrogen (H) atmosphere of inside the reaction chamber 31 is changed to an ammonia atmosphere, and the surface of the PSS 2 is azotized. Next, the temperature of the PSS 2 decreases to 585° C. Subsequently, trimethylgallium and ammonia gas are supplied from the shower head 34. Accordingly, low-temperature buffer layer including microcrystal of gallium nitride (GaN) is formed to be about 40 nm thick. The microcrystal of gallium nitride (GaN) is to be a core for growing. Then, the temperature of the PSS 2 increases 1100° C. and the n-GaN buffer layer 3 grows to be about 5 μm thick.

Subsequently, the n-GaN contact layer 4, the emission layer 5 and the p-GaN layer 6 are grown to form the multi layer 10. Conditions of growth for each of the n-GaN contact layer 4, the emission layer 5 and the p-GaN layer 6 depends on each of layers.

Next, we explain crystal quality of the nitride semiconductor formed on the PSS 2 by using the method for manufacturing a semiconductor element according to this embodiment with reference to FIG. 6 to FIG. 15. FIG. 6A and FIG. 6B are photographs by a SEM (Secondary Electron Microscopy) showing the convex portions 2b formed on the surface of the PSS 2. FIG. 6A shows the surface of the PSS 2 after chlorine pre-treatment. FIG. 6B shows the surface of the PSS 2 before chlorine pre-treatment. According to the FIG. 6A and FIG. 6B, there is no difference between the surfaces with and without chlorine pre-treatment. This means it is difficult to observe change due to the chlorine pre-treatment based on appearance.

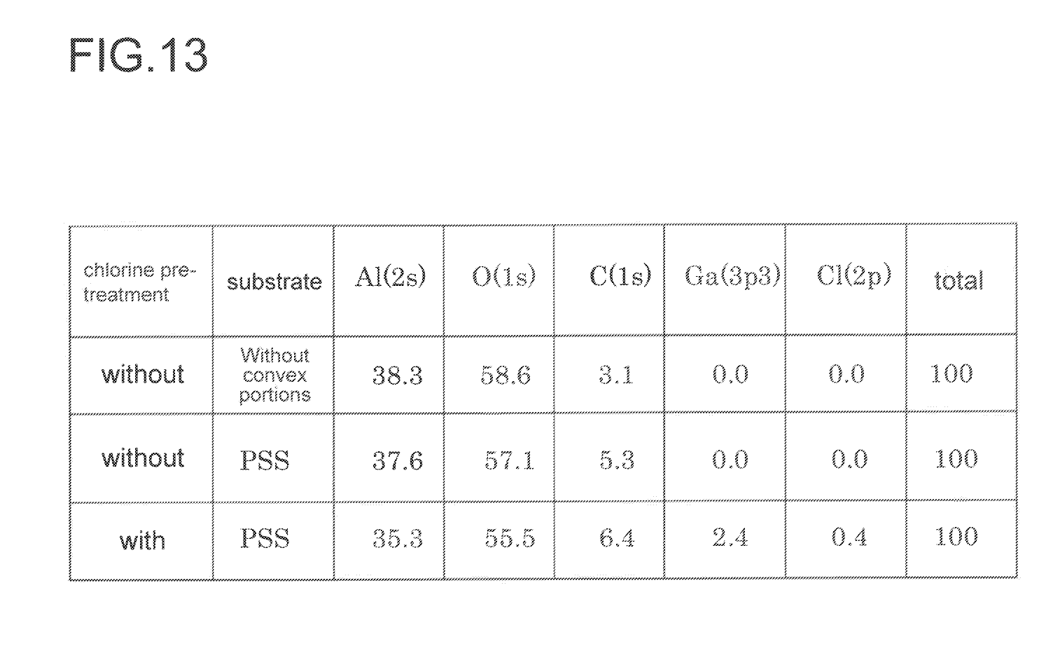

FIG. 13 is a table showing evaluation results which are obtained by evaluating the surfaces of the PSS 2 with and without chlorine pre-treatment, and a surface of a substrate without forming the convex portions 2b by XPS (X-ray Photoelectron Spectroscopy). Each of numerical numbers in FIG. 13 is atom ratio (atom %) showing elemental composition at surface of each substrate. The numerical numbers are calculated by XPS spectrum corresponding to each substrate.

In FIG. 13, chlorine (Cl) is not detected on the surfaces of both the substrate without forming the convex portions 2b and the PSS 2 without chlorine pre-treatment. Chlorine (Cl) includes in both the dry etching process for forming the convex portions 2b and the chlorine pre-treatment. Therefore, it is considered that residues due to the dry etching process do not exist on the surfaces of both the substrate without forming the convex portions 2b and the PSS 2 without chlorine pre-treatment.

On the other hand, Cl and Ga are detected on the surface of the PSS 2 with chlorine pre-treatment. Cl and Ga are included in the reaction product remaining inside the reaction chamber 31, and these Cl and Ga may be attached on the surface of the PSS 2 with chlorine pre-treatment. However, amount of each Cl and Ga detected on the surface of the PSS 2 with chlorine pre-treatment is very small. Therefore, these Cl and Ga may not give any influences for crystal quality of the nitride semiconductor formed on the PSS 2.

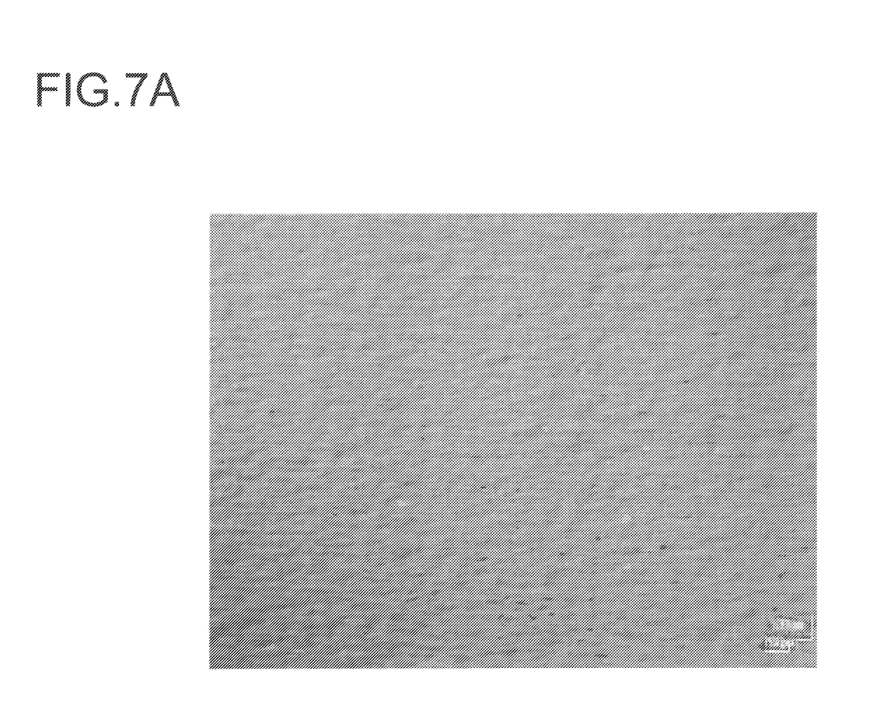

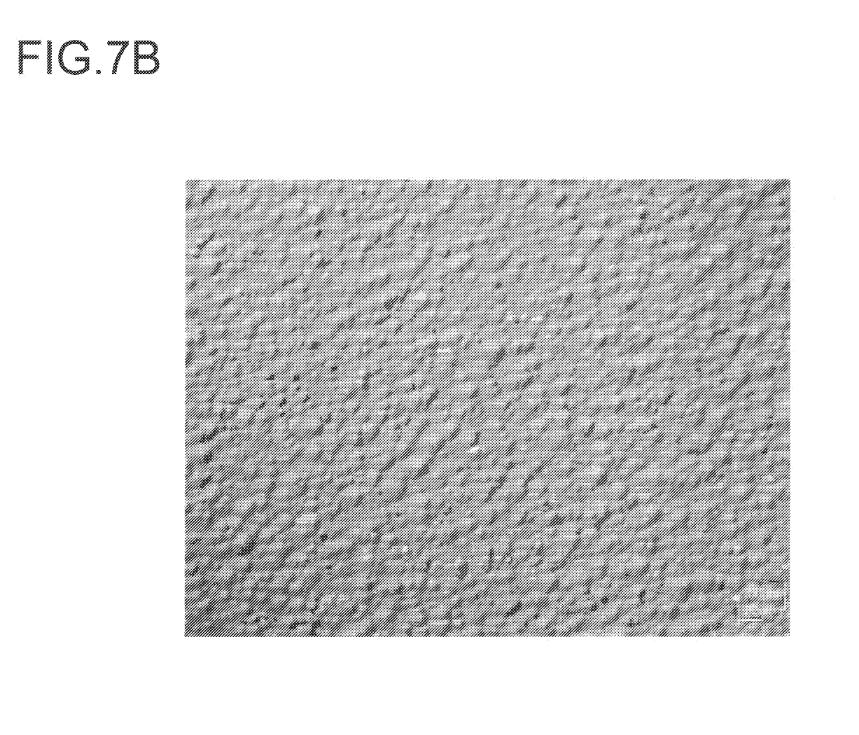

FIG. 7A is a photograph by a differential microscope showing the n-GaN buffer layer 3 with chlorine pre-treatment formed on the surface of the PSS 2. FIG. 7B is a photograph by the differential microscope showing an n-GaN layer without chlorine pre-treatment formed on the surface of the PSS 2. The surface of the n-GaN buffer layer 3 shown in FIG. 7A is flatter than the surface of the n-GaN layer shown in FIG. 7B.

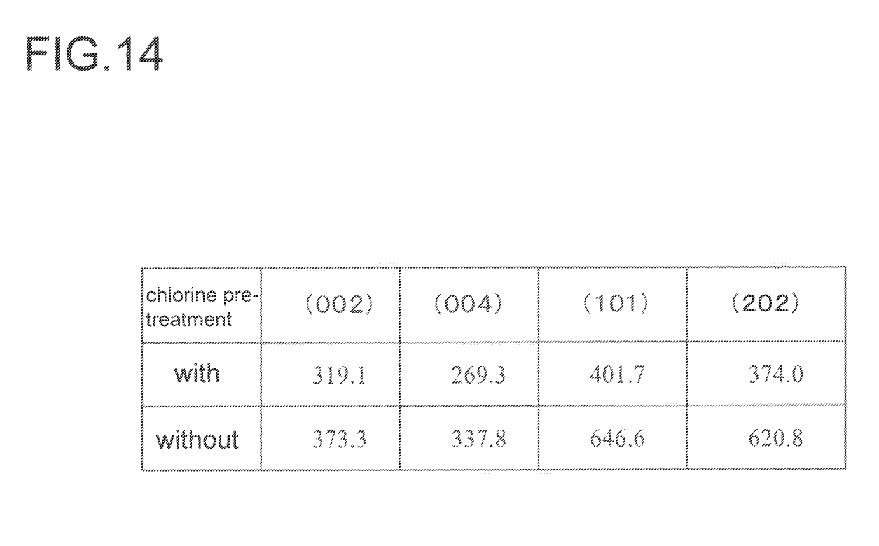

FIG. 14 is a table showing half width of XRC (Xray Rocking Curve) for the n-GaN buffer layer 3 with chlorine pre-treatment and the n-GaN layer without chlorine pre-treatment. In FIG. 14, the half width of the n-GaN buffer layer 3 is narrower than the n-GaN layer. Specifically, the n-GaN buffer layer 3 has 15% and 20% narrower half widths compared with the n-GaN layer on symmetry planes of (002) and (004), respectively. Also, the n-GaN buffer layer 3 has about 40% narrower half widths compared with the n-GaN layer on asymmetry planes of (101) and (202).

This means that the n-GaN buffer layer 3 achieves less disarray of crystal axis and crystal plane than the n-GaN layer. Therefore, chlorine pre-treatment improves the crystal quality of the nitride semiconductor formed on the PSS 2.

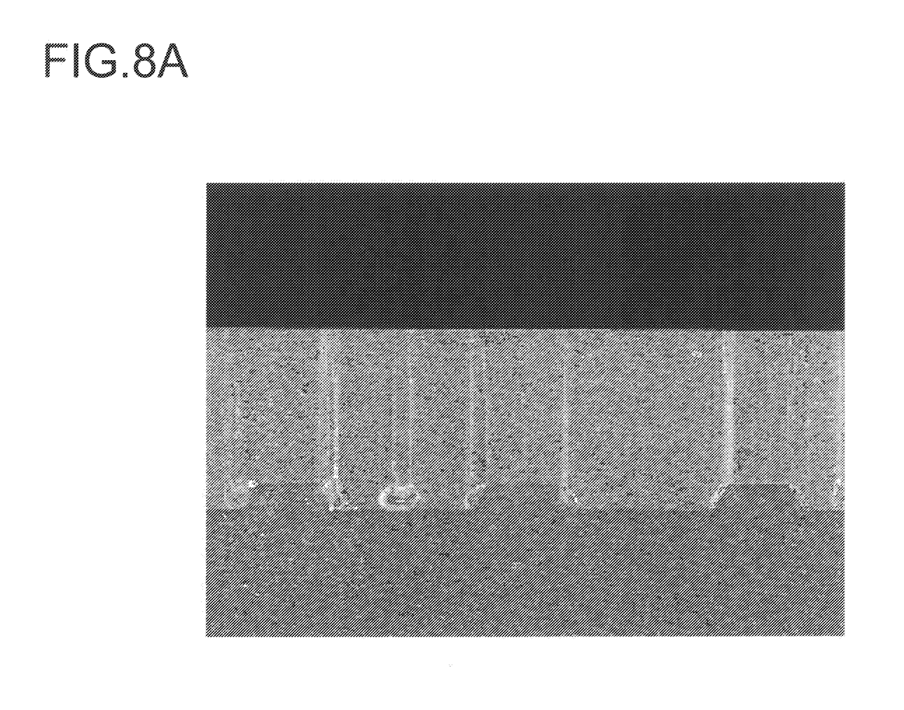

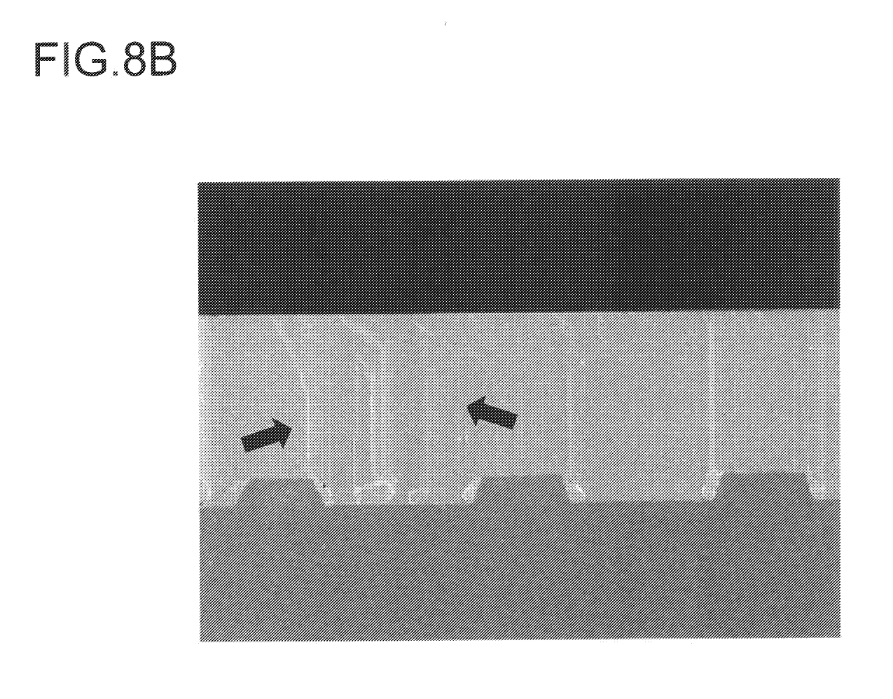

FIG. 8A is a photograph by the SEM showing a cross-section of the PSS 2 having the n-GaN buffer layer 3 formed with chlorine pre-treatment. FIG. 8B is a photograph by the SEM showing a cross-section of the PSS 2 having the n-GaN layer formed without chlorine pre-treatment.

In FIG. 8B, two arrows indicates an area having higher density of threading dislocation which reaches from a surface of the PSS 2 to a surface of the n-GaN layer. On the other hand, in FIG. 8A, the area having higher density of threading dislocation is not found. Therefore, the n-GaN buffer layer 3 has a low dislocation density.

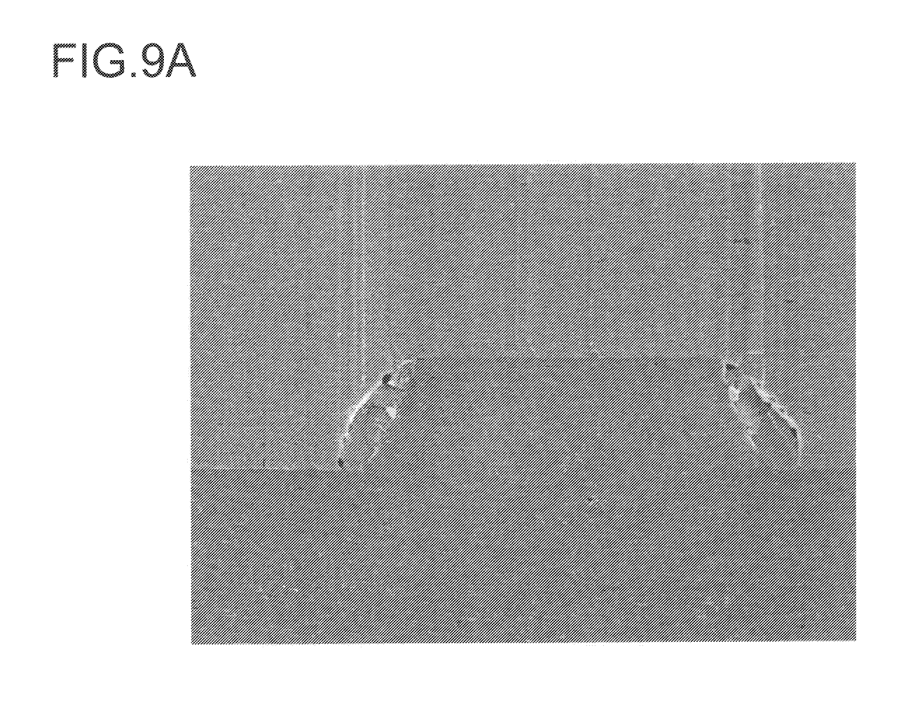

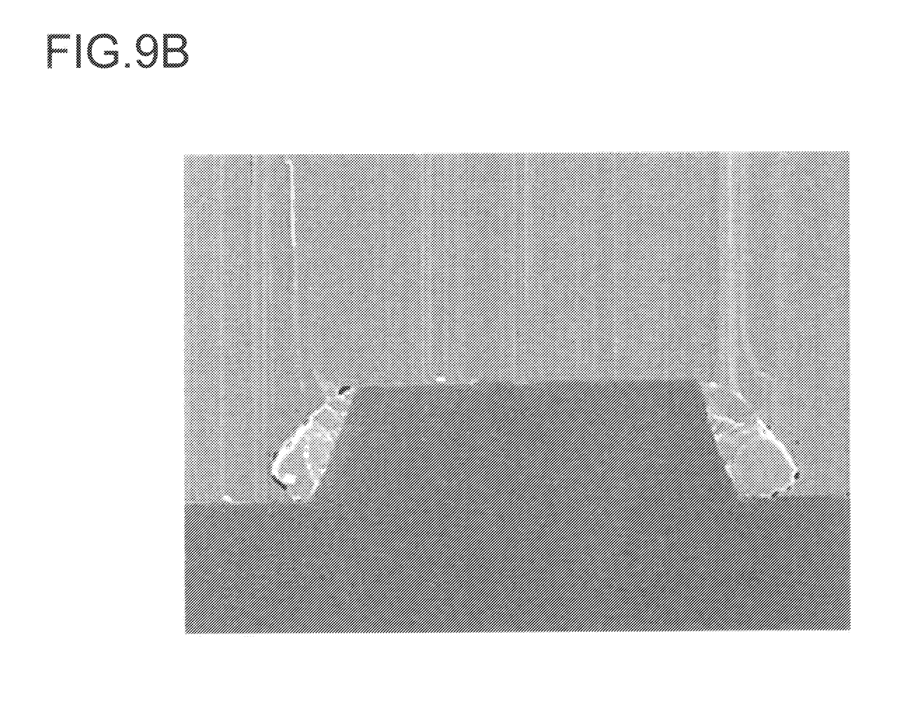

FIG. 9A is a photograph by the SEM showing a cross-section of the convex portion 2b formed on the PSS 2 having the n-GaN buffer layer 3 formed with chlorine pre-treatment. FIG. 9B is a photograph by the SEM showing a cross-section of the convex portion 2b formed on the PSS 2 having the n-GaN layer formed without chlorine pre-treatment.

In both FIG. 9A and FIG. 9B, anomalous growth are found on sides of the convex portion 2b. Also, the n-GaN buffer layer 3 shown in FIG. 9A has a less threading dislocation compared with the n-GaN layer shown in FIG. 9B.

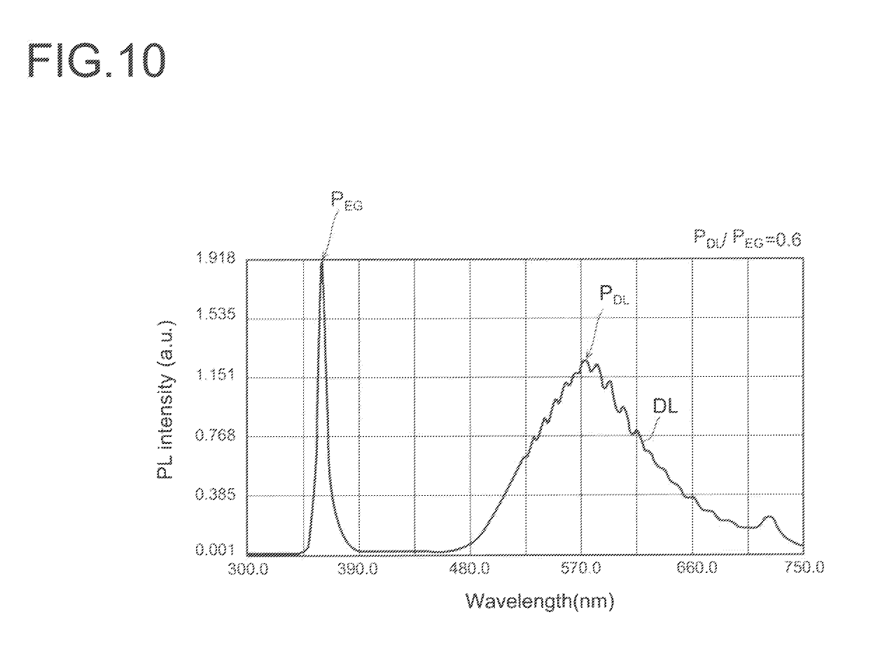

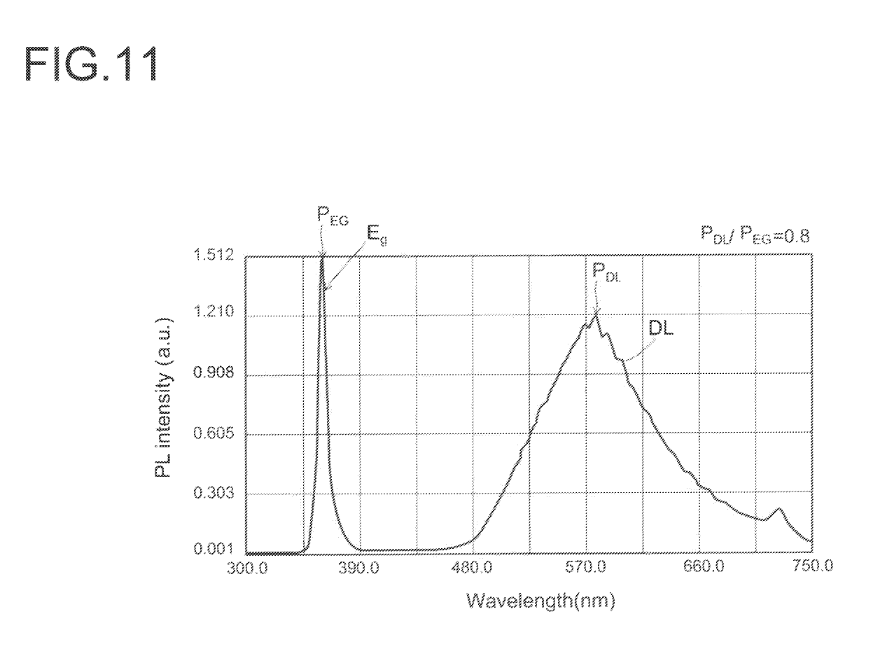

FIG. 10 is a graph showing a PL (Photoluminescence) spectrum of the n-GaN buffer layer 3. FIG. 11 is a graph showing a PL spectrum of the n-GaN layer. Both PL spectrums are measured at room temperature. In measurements, a laser beam having a wavelength of 325 nm is used as an excitation light source.

In FIG. 10, the PL spectrum has an emission peak P_{EG} at around the wavelength of 360 nm. The emission peak P_{EG} has a sharp shape having a narrow half width. Also, in FIG. 10, the PL spectrum has an emission peak P_{DL} at around the wavelength of 570 nm. The emission peak P_{DL} has a thick shape having a broad half width. The emission peak P_{EG} is due to band-edge emission of GaN crystal. The emission peak P_{DL} is a deep level (DL) emission due to defection in GaN crystal.

Similarly, in FIG. 11, the PL spectrum has the emission peak P_{EG} at around the wavelength of 360 nm and the emission peak P_{DL} at around the wavelength of 570 nm.

Intensity ratio of between the emission peak P_{DL} and the emission peak P_{EG} (P_{DL}/P_{EG}) is about 0.6 in the n-GaN buffer layer 3 of FIG. 10. Intensity ratio of between the emission peak P_{DL} and the emission peak P_{EG} (P_{DL}/P_{EG}) is about 0.8 in the n-GaN layer of FIG. 11. This means that the n-GaN buffer layer 3 has a less deep level compared with the n-GaN layer. Therefore, the crystal quality of the n-GaN buffer layer 3 is improved.

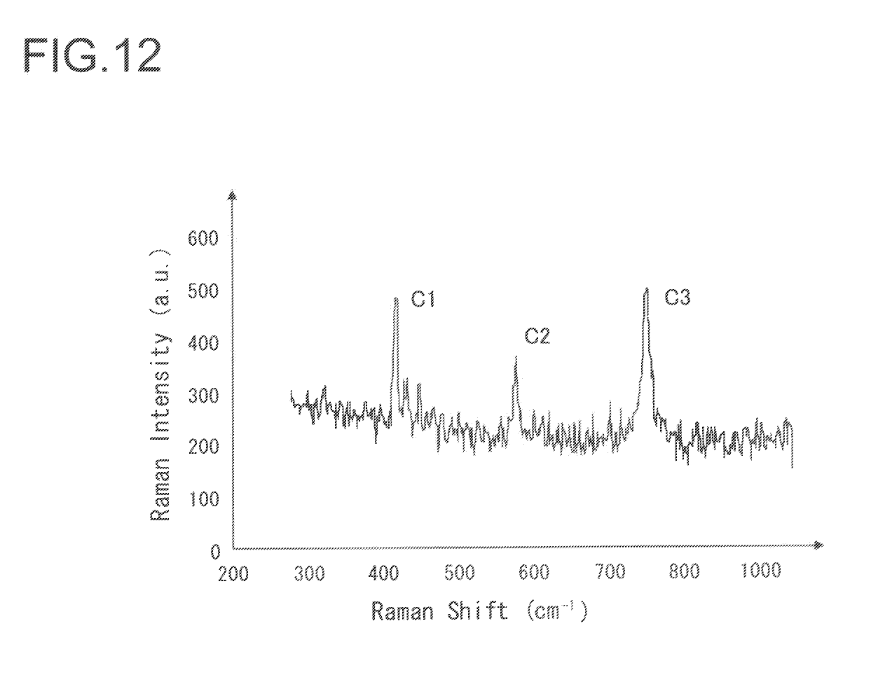

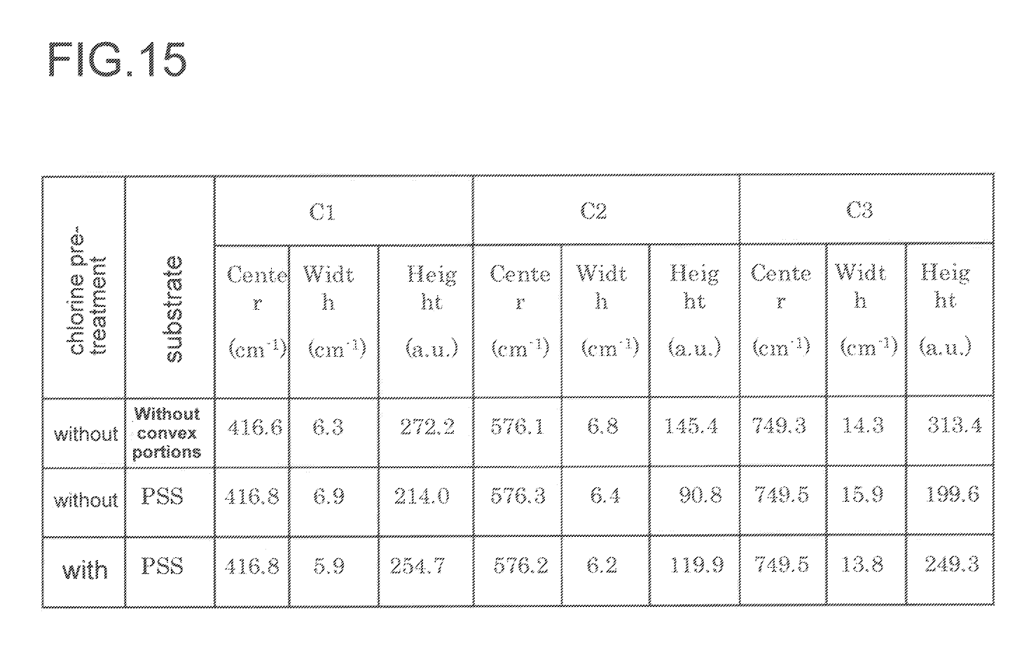

FIG. 12 is a graph showing a micro-raman scattering spectrum of the PSS 2. FIG. 15 is a table showing measurement data of the micro-raman scattering spectrum. The measurement data include a peak position (Center), a half width (Width), and a raman scattering intensity (Height) in the micro-raman scattering spectrum. We measured the micro-raman scattering spectrums of the surfaces of the PSS 2 with and without chlorine pre-treatment, and a surface of a substrate without forming the convex portions 2b.

Each data is an average value of values obtained by fitting a spectrum with using Lorents curve. The spectrum is measured at three points in an area of 10 mmφ at a center of wafer. In FIG. 15, C1, C2, and C3 are corresponding to the three main peaks of the spectrum shown in FIG. 12, respectively.

According to FIG. 15, the peak position (Center) is independent from with and without chlorine pre-treatment. The peak position (Center) is also independent from with and without the dry etching process for forming the convex portions 2b. On the other hand, the half width (Width) of the PSS 2 with the dry etching process and without chlorine pre-treatment is broader than that of the surface of a substrate without dry etching for forming the convex portions 2b. Also, the half width (Width) of the PSS 2 with the dry etching process and with chlorine pre-treatment is narrower than that of the PSS 2 with the dry etching process and without chlorine pre-treatment. This means the half width (Width) becomes broader by the dry etching process and narrower by chlorine pre-treatment.

The raman scattering intensity (Height) becomes smaller by the dry etching process and larger by chlorine pre-treatment.

In the micro-raman scattering spectrum, a shift of the peak is corresponding to strain and stress, and the half width is corresponding to the crystal quality. According to the half width in FIG. 15, the crystal quality of the PSS 2 is degraded by the dry etching and improved by the chlorine pre-treatment. Moreover, according to the raman scattering intensity (Height) in FIG. 15, the strain due to the dry etching process is recovered by the chlorine pre-treatment.

Generally, in the dry etching process, atomic arrangement is disrupted by irradiation of energetic particles and a damage layer is formed. The crystal quality of the nitride semiconductor formed on the PSS 2 after the dry etching process is affected by the damage layer. The damage layer is almost not etched by a chemical solution such as HF and HCl. Therefore, it is difficult to remove the damage layer and to form the nitride semiconductor having high crystal quality on the PSS 2 after dry etching process.

On the other hand, in this embodiment, the damage layer due to the dry etching process is removed by the chlorine pre-treatment. Then, the crystal quality of the nitride semiconductor formed on the PSS 2 is improved.

Therefore, the method for manufacturing semiconductor element according to this embodiment can form the nitride semiconductor having high crystal quality on the substrate after dry etching. As a result, the method for manufacturing semiconductor element according to this embodiment improves quality of the semiconductor element and improves fabrication yield.

Moreover, in the method for manufacturing semiconductor element according to this embodiment, heat treatment in a hydrogen (H) atmosphere can be performed in a reaction chamber used for forming the nitride semiconductor. Accordingly, reaction product attached inside the reaction chamber 31 during MOCVD growth can be removed by the chlorine pre-treatment. This means that the reaction product attached inside the reaction chamber 31 can be removed at each of repeated growth processes. As a result, cleaning process of the reaction chamber 31 can be omitted. Also, since cycle of cleaning the reaction chamber 31 becomes longer, productivity can be improved.

While certain embodiments have been described, these embodiments have been presented by way of example only, and are not intended to limit the scope of the inventions. Indeed, the novel systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and spirit of the inventions.

In this embodiment, “the nitride semiconductor” may include III-V compound semiconductors of BₓIn_{y}Al_{z}Ga_{(1-x-y-z)}N (0≦x≦1, 0≦y≦1, 0≦z≦1, 0≦x+y+z≦1). Moreover, group V element may include mixed crystal including nitrogen (N), phosphorus (P) and arsenic (As). Furthermore, “the nitride semiconductor” may include some elements added for controlling a property such as conductivity type and any elements included as unexpected.

What is claimed is:

1. A method for manufacturing a semiconductor element, comprising:
etching a surface of a substrate by a dry etching processing;
performing a first heat treatment for the surface of the substrate in an atmosphere including halogen; and
forming a nitride semiconductor on the surface of the substrate.

2. The method of claim 1, wherein at least one concave portion is formed on the surface of the substrate in the dry etching processing.

3. The method of claim 1, wherein the surface of the substrate is heated to be a temperature of over 650° C. in the first heat treatment.

4. The method of claim 2, wherein the surface of the substrate is heated to be a temperature of over 650° C. in the first heat treatment.

5. The method of claim 1, wherein the halogen is chlorine.

6. The method of claim 2, wherein the halogen is chlorine.

7. The method of claim 3, wherein the halogen is chlorine.

8. The method of claim 4, wherein the halogen is chlorine.

9. The method of claim 1, wherein the substrate is a sapphire substrate.

10. The method of claim 2, wherein the substrate is a sapphire substrate.

11. The method of claim 3, wherein the substrate is a sapphire substrate.

12. The method of claim 4, wherein the substrate is a sapphire substrate.

13. The method of claim 1, further comprising performing a second heat treatment for the surface of the substrate with temperature of more than 1000° C. and less than 1500° C. in an atmosphere including hydrogen, after performing the first heat treatment and before forming the nitride semiconductor.

14. The method of claim 2, further comprising performing a second heat treatment for the surface of the substrate with temperature of more than 1000° C. and less than 1500° C. in an atmosphere including hydrogen, after performing the first heat treatment and before forming the nitride semiconductor.

15. The method of claim 3, further comprising performing a second heat treatment for the surface of the substrate with temperature of more than 1000° C. and less than 1500° C. in an atmosphere including hydrogen, after performing the first heat treatment and before forming the nitride semiconductor.

16. The method of claim 4, further comprising performing a second heat treatment for the surface of the substrate with temperature of more than 1000° C. and less than 1500° C. in an atmosphere including hydrogen, after performing the first heat treatment and before forming the nitride semiconductor.

17. The method of claim 1, wherein the first heat treatment is performed in a reaction chamber used for forming the nitride semiconductor.

18. The method of claim 2, wherein the first heat treatment is performed in a reaction chamber used for forming the nitride semiconductor.

19. The method of claim 3, wherein the first heat treatment is performed in a reaction chamber used for forming the nitride semiconductor.

20. The method of claim 4, wherein the first heat treatment is performed in a reaction chamber used for forming the nitride semiconductor.
